(19) United States
(12) Patent Application Publication
(10) Pub. No.: US 2013/0126826 A1
(43) Pub. Date: May 23, 2013

(54) Optical Tilted Charge Devices And Methods

(71) Applicant: Quantum Electro Opto Systems Sdn. Bhd., Melaka (MY)

(72) Inventor: Gabriel Walter, Madison, WI (US)

(73) Assignee: Quantum Electro Opto Systems Sdn. Bhd., Melaka (MY)

(21) Appl. No.: 13/675,245

(22) Filed: Nov. 13, 2012

Related U.S. Application Data
(60) Provisional application No. 61/629,181, filed on Nov. 14, 2011.

(51) Int. Cl. H01L 33/06; H01L 33/00

(52) U.S. Cl. CPC H01L 33/06; H01L 33/002
USPC 257/13; 438/47

(57) ABSTRACT

A method for making an optical tilted-charge device that is substantially matched to GaAs lattice constant, including the following steps: providing a layered semiconductor structure that includes: a GaAs substrate; a semiconductor collector region; a semiconductor base region that includes a doped GaAs second base sub-region, an InGaAsN quantum size region, and a doped GaAs first base sub-region; and a semiconductor emitter region; and providing collector, base, and emitter electrodes respectively coupled with the collector region, the base region, and the emitter region. Electrical signals, applied with respect to the collector, base, and emitter electrodes, produces light emission from the base region.

### PRIORITY CLAIM

Priority is claimed from U.S. Provisional Patent Application No. 61/629,181, filed Nov. 14, 2011, and said Provisional patent application is incorporated herein by reference.

### RELATED APPLICATION

The subject matter of this application is related to subject matter of U.S. patent application Ser. No. ______, filed of even date herewith and assigned to the same assignee as the present application.

### FIELD OF THE INVENTION

This invention relates to the field of semiconductor light emitting devices and techniques and, more particularly, to tilted charge light emitting devices and methods.

### BACKGROUND OF THE INVENTION

Included in the background of the present invention are technologies relating to heterojunction bipolar transistors (HBTs, which are electrical tilted charge devices) and light-emitting transistors, transistor lasers, and tilted charge light-emitting diodes (respectively, LETs, TLs, and TCLEDs, all of which are optical tilted charge devices). A tilted charge device gets its name from the energy diagram characteristic in the device's base region, which has, approximately, a descending ramp shape from the emitter interface to the collector (or drain, for a two terminal device) interface. This represents a tilted charge population of carriers that are in dynamic flow—“fast” carriers recombine, and “slow” carriers exit via the collector (or drain).

Regarding optical tilted charge devices and techniques, which typically employ one or more quantum size regions in the device's base region, reference can be made, for example, to U.S. Pat. Nos. 7,091,082, 7,286,583, 7,354,780, 7,535,034, 7,693,195, 7,696,536, 7,711,015, 7,813,396, 7,888,199, 7,888,625, 7,953,133, 7,998,807, 8,005,124, 8,179,937, and 8,179,939; U.S. Patent Application Publication Numbers US2005/0040432, US2005/0054172, US2008/0240173, US2009/0134939, US2010/0034228, US2010/0202483, US2010/0202484, US2010/0272140, US2010/0289427, US2011/0150487, and US2012/0068151; and to PCT International Patent Publication Numbers WO/2005/020287 and WO/2006/093883 as well as to the publications referenced in U.S. Patent Application Publication Number US2012/0068151.

An optical tilted charge device includes an active region with built-in free majority carriers of one polarity. At one input to this active region, a single species of minority carriers of opposite polarity are injected and allowed to diffuse across the active region. This active region has features that enable and enhance the conduction of majority carriers and the radiative recombination of minority carriers. On the output side of the region, minority carriers are then collected, drained, depleted or recombined by a separate and faster mechanism. Electrical contacts are coupled to this full-featured region.

In the U.S. Patent Application Publication No. US2010/202484, assigned to an entity that includes the assignee of the present Application, there is shown, as background, a QW-heterojunction bipolar light emitting transistor (QW-HBLET) with a deep QW design and homogeneous doped base region. Reference can be made, for example, to the patents referenced above. The relatively deep QW assists captured carriers to spread laterally and recombine away from the optical cavity. In addition to that, as the carriers spread laterally, the carriers can also rethermalize and carriers that rethermalize towards the emitter (back diffusion) are mostly lost in to non-radiative recombination. As an improvement thereto, an asymmetrical base region was set forth, having a relatively wider bandgap base sub-region on the emitter side the QW as compared to a relatively narrow bandgap sub-region on the collector side. Also, one or more shallow quantum wells were used for reasons that include limiting diffusion of captured carriers and increasing speed.

Applicant's research has indicated that the use of heavily doped high composition alloy (e.g. ternary or quaternary material) in the base region of an optical tilted charge device (OTCD), can result in significantly higher non-radiative recombination (η_{non-rad} ˜30% to 90% of base recombination). Some of this research has been focused on the use of a relatively shallow InGaAs quantum well (ΔE, the quantum well depth energy, is a small multiple of kT, ΔE˜kT) with emission photon energies that can be coupled to InP/InGaAs based photodetectors. (See also the above-referenced Published Application US 2010/0202484.) The use of a shallow quantum well allows the utilization of phonons as a method to increase the speed of the optical tilted charge device. However, there are certain applications of optical tilted charge devices where a deep quantum well (ΔE>>kT) is advantageous, and device speed is of a lesser concern; for example, in optical devices that require high base current density operations and stable current gain under varying bias current characteristics or temperature. For such applications, use of a high composition alloyed base (e.g. AlGaAs), with its attendant disadvantage, would appear inevitable.

It is among the objects of the present invention to provide improvements in optical tilted charge devices that need to use relatively deep quantum wells, while avoiding concomitant drawbacks.

### SUMMARY OF THE INVENTION

The design of a practical optical tilted charge device includes several complex considerations including achievement of high internal quantum efficiency, manufacturability, compatibility and reliability. Therefore, transitioning from an existing design of an optical tilted charge device to another presents challenges. In accordance with an aspect of the present invention, there is provided an optical tilted charge device with a deep quantum well (with ΔE at least about 0.25 eV>>kT) while maintaining a heavily doped base region that is substantially binary. The optical tilted charge device with these features is still capable of incorporating etch stop layers that selectively stop etching at one type of semiconductor material, to assist in the definition of the emitter mesa, base mesa and collector mesa which benefits manufacturability. In addition, for reliability reasons, the base region can still be doped with carbon (p-type, NPN structure) or silicon (n-type, PNP). Compatibility is maintained, since the emission photon energies of the optical tilted charge device can still be coupled to existing InP/InGaAs based photodetectors. A further advantage is that the disclosed GaAs based optical tilted charge device hereof is compatible with the use of silicon-based substrates and lenses.

In accordance with a form of the invention, a method is provided for making an optical tilted-charge device that is substantially matched to GaAs lattice constant, including the following steps: providing a layered semiconductor structure that includes: a GaAs substrate; a semiconductor collector region; a semiconductor base region that includes a doped GaAs second base sub-region, an InGaAsN quantum size region, and a doped GaAs first base sub-region; and a semiconductor emitter region; and providing collector, base, and emitter electrodes respectively coupled with said collector region, said base region, and said emitter region. Electrical signals, applied with respect to said collector, base, and emitter electrodes, produces light emission from said base region. In an embodiment of this form of the invention, the step of providing said collector and emitter regions comprises providing said regions as substantially GaAs, and the step of providing said second and first base sub-regions comprises providing said second and first base sub-regions as being heavily doped p-type (where, as used herein, heavily doped means at least about 10¹⁸ cm⁻³ for p-type and 10¹⁷ cm⁻³ for n-type). Also in this embodiment, the step of providing said InGaAsN quantum size region comprises providing an InGaAsN quantum well between GaAs barrier layers. Alternatively, the step of providing said InGaAsN quantum size region can comprise providing a plurality of InGaAsN quantum wells, each between GaAs barrier layers. Also in this embodiment, the method includes growing said layered semiconductor structure with intervening InAlGaP alloy etch stop layers for defining base and emitter mesas using an etchant that selectively removes arsenide-based materials. (The InAlGaP alloy for this etch stop application also includes the use of InGaP or InAlAs etch stop layers.) In a form of this embodiment, the layered semiconductor structure is deposited on a GaAs-on-Si substrate, and a Si lens is formed from said substrate.

In another form of the invention, a method is set forth for making a two-terminal optical tilted-charge device that is substantially matched to GaAs lattice constant, including the following steps: providing a layered semiconductor structure that includes: a GaAs substrate; a semiconductor drain region; a semiconductor base region that includes a doped GaAs second base sub-region, an InGaAsN quantum size region, and a doped GaAs first base sub-region; and a semiconductor emitter region; and providing a base/collector electrode coupled with said collector and base regions, and an emitter electrode coupled with said emitter region. Electrical signals, applied with respect to said base/drain and emitter electrodes, produces light emission from said base region.

In a further form of the invention, there is set forth an optical tilted-charge device that is substantially matched to GaAs lattice constant, comprising: a layered semiconductor structure that includes: a GaAs substrate; a semiconductor collector region; a semiconductor base region that includes a heavily doped GaAs second base sub-region, an InGaAsN quantum size region, and a heavily doped GaAs first base sub-region; and a semiconductor emitter region; said collector and emitter regions being of opposite conductivity type to the conductivity type of said base sub-regions; and collector, base, and emitter electrodes respectively coupled with said collector region, said base region, and said emitter region; whereby application of electrical signals with respect to said collector, base, and emitter electrodes will produce light emission from said base region. In an embodiment of this form of the invention, the InGaAsN quantum size region in said base region comprises a quantum well having a depth of at least about 0.25 eV. In this embodiment, the InGaAsN quantum size region comprises an InGaAsN quantum well between GaAs barrier layers. Preferably, the InGaAsN quantum size region comprises InₓGa₁₋ₓAsN with x at least about 0.3. Also in this embodiment, the GaAs substrate is disposed on silicon, and said silicon is in the form of a lens.

Further features and advantages of the invention will become more readily apparent from the following detailed description when taken in conjunction with the accompanying drawings.

### BRIEF DESCRIPTION OF THE DRAWINGS

FIG. 1 is a cross-sectional view of an optical tilted charge device, in the form of a light-emitting transistor, in accordance with an embodiment of the invention and which can be used in practicing an embodiment of the method of the invention.

FIG. 2 is a table showing the epilayer structure of an example of the FIG. 1 embodiment of the invention.

FIG. 3 is a table showing epilayer structure of a device in accordance with another embodiment of the invention.

FIG. 4 is a cross-sectional view of another optical tilted charge device, in the form of a two-terminal tilted charge light-emitting diode, in accordance with an embodiment of the invention and which can be used in practicing an embodiment of the method of the invention.

### DETAILED DESCRIPTION

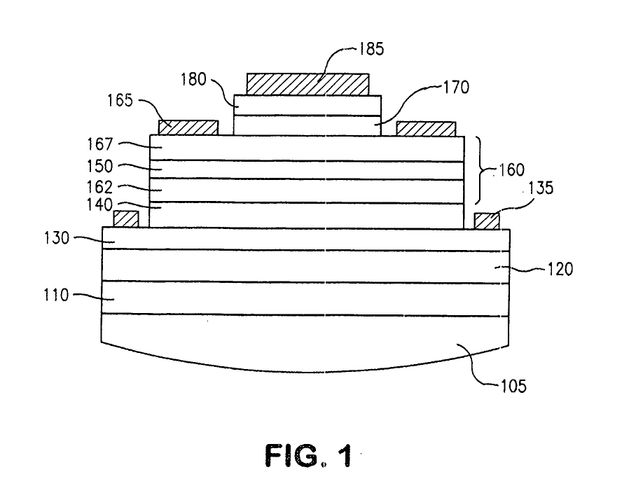

FIG. 1 shows a device in accordance with an embodiment of the invention, and which can be used in practicing an embodiment of the method of the invention. The semiconductor layering shown in FIG. 1, from the bottom up, includes: a GaAs substrate 110; a GaAs buffer region 120; a sub-collector region 130; a collector region 140; a base region 160 that includes a base sub-region 162 called “base-2”, a quantum size region 150 (one or more quantum wells or other suitable quantum size regions such as quantum dots or quantum wires), a base sub-region 167 called “base-1”, an emitter region 170, and a sub-emitter region 180. In accordance with a feature hereof, an InGaAsN quantum size region is employed in the base region. The collector, base, and emitter electrodes are shown respectively as metal collector contact 135 (which contacts the subcollector region), metal base contact 165 (which contacts the base-1 region), and metal emitter contact 185 (which contacts the sub-emitter region). A collimator or focusing lens 105 can be molded to or affixed to the GaAs substrate 110. The collimator or lens 105 can be advantageously formed of silicon. When the device is grown on a GaAs-on-Si substrate, the lens can be formed by etching the silicon. Although a bottom light emitter is shown, the device can also be configured as a top emitter.

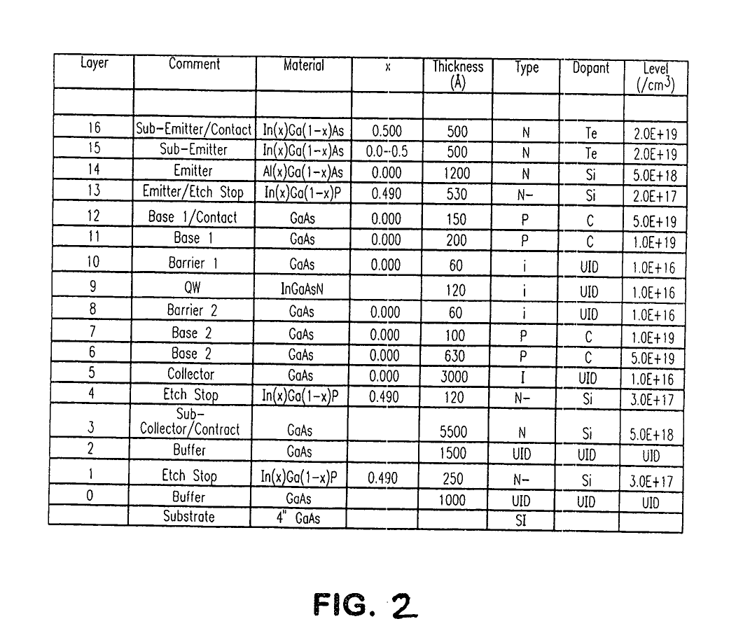

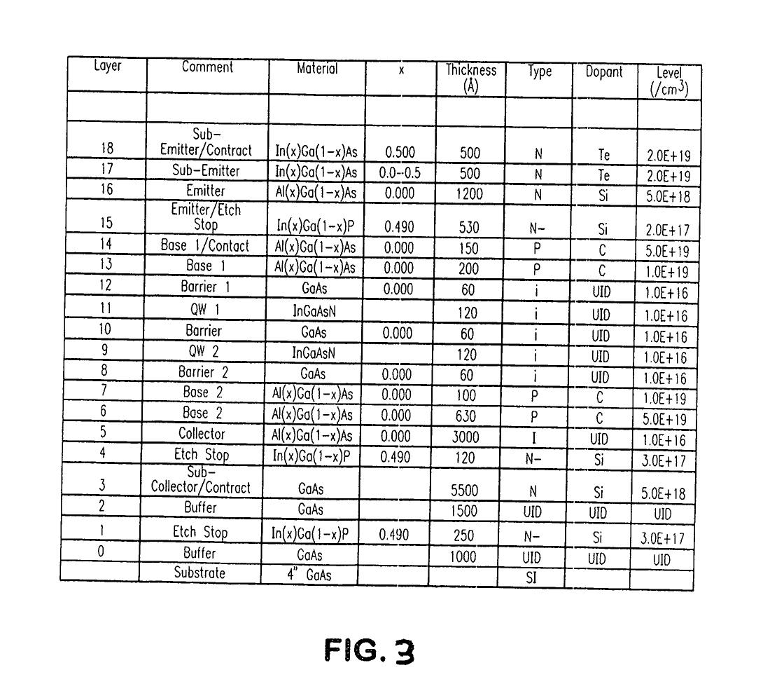

The table of FIG. 2 shows the more detailed semiconductor epilayers of an example of the FIG. 1 embodiment. The epilayer structure can be made using existing MOCVD (metalorganic vapor deposition) and/or MBE (molecular beam epitaxy) deposition techniques, and the devices formed using existing photolithography techniques. The base-2 region includes a p-type GaAs layer (layer 6), followed by a lower doped p-type GaAs material (layer 7) to complete the base-2 region. The dopant is reduced closer to the quantum well to reduce the diffusion of dopants into the quantum well region. The dopant for the p-type base region is preferably carbon, which has a relatively abrupt diffusion tail compared to most other p-type dopants such as zinc. Then, a quantum well structure including an unintentionally doped GaAs layer (layer 8) is grown to form the first barrier layer, followed by a thin (˜120 A) lower bandgap InGaAsN layer, which is substantially lattice matched to GaAs (layer 9), and then completed with another thin GaAs layer as the second barrier layer (layer 10). A multiple quantum well structure may alternatively be implemented by using repetitious layers of InGaAsN and GaAs barrier layers, as shown in the table of FIG. 3. The active base region of the device is then completed with the growth of the base-1 structure, including lower doped p-type GaAs layer (layer 11) and a higher doped GaAs contact layer (layer 12). Layer 14 is shown in the table as having a possibility of aluminum content, such as for index step or confinement using lateral oxidation.

InGaAsN semiconductor material, advantageously used for the quantum well hereof, is a quaternary material which uses smaller nitrogen atoms to compensate for the strain induced by the larger indium atoms, allowing the material to remain substantially matched to GaAs lattice constant. This allows higher incorporation of indium to lower the energy gap of the InGaAsN layer, resulting in a deeper quantum well, without having to increase the energy gap of the barrier layers which would require resorting to ternary composition.

The use of InGaAsN material for the quantum well also allows for the design of devices with emission peak longer than 1100 nm, which has relatively high transmission through silicon. This allows the optical tilted charge devices to be advantageously coupled to high index silicon lenses (as in FIG. 1). Since the entire OTCD structure is substantially lattice matched to GaAs lattice constants, and the emission wavelength can be tailored to enable the use of silicon lenses, the disclosed devices can be directly grown on GaAs-on-Si substrates, and the lens etched from the Si. Also, for GaAs substrates, an alternative is to etch a lens in the GaAs.

In the present embodiment, low doped, and substantially matched to GaAs lattice constant, InAlGaP alloy (e.g. In_{0.49}Ga_{0.51}P) etch stop layers are placed in Layer 1, 4 and 13, which also define the boundaries for the base contact layer (layer 13), the collector contact layer (layer 3) and the boundary (layer 1) between the doped and undoped buffers. Layer 1 can be used to assist in the GaAs substrate removal or device isolation by allowing all conducting material to be removed and therefore electrically decoupling one device from another adjacent device. These phosphide based materials (e.g. InGaP or InAlGaP) are stable relative to etchant used to remove the arsenide based materials such as GaAs and InGaAs. Likewise, the phosphide based materials can be removed using etchant that is stable against arsenide based material. Accordingly, the phosphide based materials can be removed without affecting the arsenide materials and vice versa. A partial DBR or full DBR cavity may also be incorporated into this structure. This embodiment, and others hereof, can also be operated as a laser by providing a suitable resonant optical cavity.

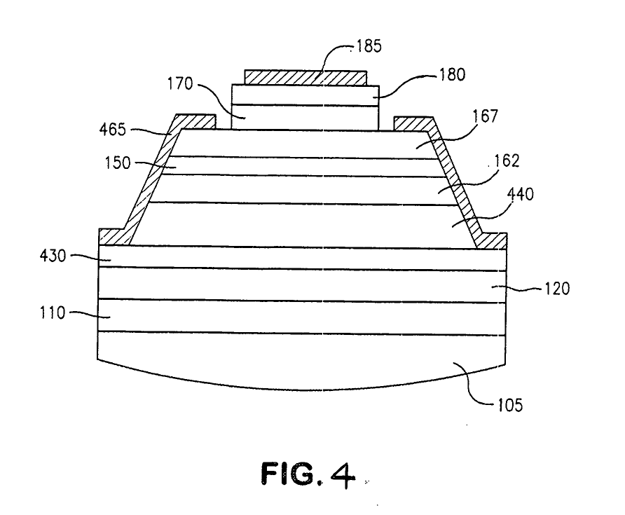

In a further embodiment, the features of the invention are employed in a two terminal tilted-charge light-emitting diode, of the general type disclosed in U.S. Patent Application Publication No. US2010/0202483 or U.S. Patent Application Publication No. US2012/0068151. In this device, the structure of the FIG. 1 embodiment is varied, with the region beneath the base region being designated a drain region, and a peripheral base/drain electrode being coupled with the base region and the drain region. An example is shown in FIG. 4, in which lens 105, substrate 110, buffer region 120, base-1 region 162, quantum size region 150, base-2 region 167, emitter region 170, sub-emitter region 180, and emitter contact 185 are similar to elements of like reference numerals in FIG. 1. Instead of subcollector and collector, regions, however, the FIG. 4 device has subdrain region 430 and drain region 440. Also, instead of base and collector electrodes, the device of this embodiment has a base/drain electrode 465. As described in the above-referenced Patent Application Publications, application of electrical signals to said base/drain and emitter electrodes produces light emission from the base region. The tilted-charge light-emitting diode of this embodiment has the same advantages in fabrication and operation as the three terminal optical tilted charge device of the FIG. 1 embodiment.

The invention has been described with reference to particular preferred embodiments, but variations within the spirit and scope of the invention will occur to those skilled in the art. For example, while npn light-emitting transistors have been described, it will be understood that certain principles hereof will apply as well to pnp light-emitting transistors.

1. A method for making an optical tilted-charge device that is substantially matched to GaAs lattice constant, comprising the steps of:
providing a layered semiconductor structure that includes: a GaAs substrate; a semiconductor collector region; a semiconductor base region that includes a doped GaAs second base sub-region, an InGaAsN quantum size region, and a doped GaAs first base sub-region; and a semiconductor emitter region; and
providing collector, base, and emitter electrodes respectively coupled with said collector region, said base region, and said emitter region.

2. The method as defined by claim 1, further comprising the step of applying electrical signals with respect to said collector, base, and emitter electrodes to produce light emission from said base region.

3. The method as defined by claim 1, wherein said step of providing said collector and emitter regions comprises providing said regions as substantially GaAs.

4. The method as defined by claim 1, wherein said step of providing said second and first base sub-regions comprises providing said second and first base sub-regions as being heavily doped p-type.

5. The method as defined by claim 1, wherein said step of providing said InGaAsN quantum size region comprises providing an InGaAsN quantum well between GaAs barrier layers.

6. The method as defined by claim 1, wherein said step of providing said InGaAsN quantum size region comprises providing an unintentionally doped InGaAsN quantum well between unintentionally doped GaAs barrier layers.

7. The method as defined by claim 1, wherein said step of providing said InGaAsN quantum size region comprises providing a plurality of InGaAsN quantum wells, each between GaAs barrier layers.

8. The method as defined by claim 3, further comprising growing said layered semiconductor structure with intervening InAlGaP alloy etch stop layers for defining base and emitter mesas using an etchant that selectively removes arsenide-based materials.

9. The method as defined by claim 8, wherein said step of providing InAlGaP alloy etch stop layers comprises providing InGaP etch stop layers

10. The method as defined by claim 1, further comprising providing a silicon lens on said device.

11. The method as defined by claim 1, further comprising forming said layered semiconductor structure on a GaAs-on-Si substrate, and further comprising forming a Si lens from said substrate.

12. The method as defined by claim 2, further comprising disposing said base region in an optical resonant cavity, and wherein said light emission is laser emission.

13. A method for making a two-terminal optical tilted-charge device that is substantially matched to GaAs lattice constant, comprising the steps of:
providing a layered semiconductor structure that includes: a GaAs substrate; a semiconductor drain region; a semiconductor base region that includes a doped GaAs second base sub-region, an InGaAsN quantum size region, and a doped GaAs first base sub-region; and a semiconductor emitter region; and
providing a base/collector electrode coupled with said collector and base regions, and an emitter electrode coupled with said emitter region.

14. The method as defined by claim 13, further comprising the step of applying electrical signals with respect to said emitter and base/drain electrodes to produce light emission from said base region.

15. The method as defined by claim 13, wherein said step of providing said drain and emitter regions comprises providing said regions as substantially GaAs.

16. The method as defined by claim 13, wherein said step of providing said InGaAsN quantum size region comprises providing an InGaAsN quantum well between GaAs barrier layers.

17. The method as defined by claim 13, wherein said step of providing said InGaAsN quantum size region comprises providing an unintentionally doped InGaAsN quantum well between unintentionally doped GaAs barrier layers.

18. The method as defined by claim 13, wherein said step of providing said InGaAsN quantum size region comprises providing a plurality of InGaAsN quantum wells, each between GaAs barrier layers.

19. The method as defined by claim 15, further comprising growing said layered semiconductor structure with intervening InAlGaP alloy etch stop layers for defining base/drain and emitter mesas using an etchant that selectively removes arsenide-based materials.

20. The method as defined by claim 13, further comprising forming said layered semiconductor structure on a GaAs-on-Si substrate, and further comprising forming a Si lens from said substrate.

21. The method as defined by claim 14, further comprising disposing said base region in an optical resonant cavity, and wherein said light emission is laser emission.

22. An optical tilted-charge device that is substantially matched to GaAs lattice constant, comprising:
a layered semiconductor structure that includes: a GaAs substrate; a semiconductor collector region; a semiconductor base region that includes a heavily doped GaAs second base sub-region, an InGaAsN quantum size region, and a heavily doped GaAs first base sub-region; and a semiconductor emitter region; said collector and emitter regions being of opposite conductivity type to the conductivity type of said base sub-regions; and
collector, base, and emitter electrodes respectively coupled with said collector region, said base region, and said emitter region;
whereby application of electrical signals with respect to said collector, base, and emitter electrodes will produce light emission from said base region.

23. The optical tilted-charge device as defined by claim 22, wherein said InGaAsN quantum size region in said base region comprises a quantum well having a depth of at least about 0.25 eV.

24. The optical tilted-charge device as defined by claim 22, wherein said InGaAsN quantum size region comprises an InGaAsN quantum well between GaAs barrier layers.

25. The optical tilted-charge device as defined by claim 22, wherein said collector and emitter regions comprise substantially GaAs.

26. The optical tilted-charge device as defined by claim 22, wherein said InGaAsN quantum size region comprises InₓGa₁₋ₓAsN with x at least about 0.3.

27. The optical tilted-charge device as defined by claim 22, comprising a silicon focusing lens mounted on said device.

28. The optical tilted-charge device as defined by claim 22, wherein said GaAs substrate is disposed on silicon, and wherein said silicon is in the form of a lens.

29. A method for producing optical signals, comprising the steps of:
providing a layered semiconductor structure that includes: a GaAs substrate; a semiconductor collector region; a semiconductor base region that includes a doped GaAs second base sub-region, an InGaAsN quantum size region, and a doped GaAs first base sub-region; and a semiconductor emitter region;
providing collector, base, and emitter electrodes respectively coupled with said collector region, said base region, and said emitter region; and
applying electrical signals with respect to said collector, base, and emitter electrodes to produce light emission from said base region.
